(19) United States
(12) Patent Application Publication
(10) Pub. No.: US 2007/0032056 A1
(43) Pub. Date: Feb. 8, 2007

(54) Manufacturing method of semiconductor device

(75) Inventor: Izuo Iida, Tochigi (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/491,492

(22) Filed: Jul. 24, 2006

(30) Foreign Application Priority Data
Jul. 22, 2005 (JP) 2005-212203

(51) Int. Cl. H01L 21/3205

(52) U.S. Cl. 438/585

(57) ABSTRACT

This invention relates to a technology to form a polysilicon resistor having a high resistance in a semiconductor device using a silicide process. A manufacturing method of the semiconductor device of this invention includes forming an insulation film on a semiconductor substrate, forming a polysilicon film on the insulation film, injecting a first impurity into an entire surface of the polysilicon film, forming a gate electrode and a resistor layer by patterning the polysilicon film, injecting a second impurity into the semiconductor substrate to form a source-drain region adjacent the gate electrode while the resistor layer is covered with a mask, forming a sidewall insulation film on a sidewall of the gate electrode, forming a high impurity concentration source-drain region adjacent the sidewall insulation film by injecting a third impurity into the semiconductor substrate while the resistor layer is covered with a mask, and forming titanium silicide film on a contact portion in the resistor layer, on the gate electrode and on the source-drain region.

### CROSS-REFERENCE OF THE INVENTION

This application is based on Japanese Patent Application No. 2005-212203, the content of which is incorporated herein by reference in its entirety.

### BACKGROUND OF THE INVENTION

1. Field of the Invention

This invention relates to a manufacturing method of a semiconductor device, specifically to a technology to form a polysilicon resistor having a high resistance in a semiconductor device manufactured using a silicide process.

2. Description of the Related Art

FIGS. 10A, 10B, 11A and 11B show forming steps of a salicide (self-aligned silicide) film according to a prior art, especially forming of a titanium salicide film in titanium salicide process.

First, a device isolation film 52 is formed on a semiconductor substrate 51 of one conductivity type, that is P-type for example, a gate electrode 53 is formed on an active region in the semiconductor substrate 51 through a gate insulation film, source-drain regions 54 of an opposite conductivity type, that is N⁺-type for example, are formed in a surface layer of the semiconductor substrate 51 adjacent the gate electrode 53 and then sidewall insulation film 55 is formed on each sidewall of the gate electrode 53, as shown in FIG. 10A.

Next, a metal film, a titanium (Ti) film 56 for example, is deposited over the entire surface of the semiconductor substrate 51, and the titanium film 56 is transformed into titanium silicide (TiSi₂) film 57 selectively and in a self-aligned manner in a surface layer of the gate electrode 53 and in a surface layer of the source-drain regions 54 through a thermal treatment (hereafter referred to as an RTA treatment), as shown in FIG. 10B.

After removing the titanium film 56 left on the insulation film, the titanium silicide (TiSi₂) film 57 remains in the surface layer of the gate electrode 53 and in the surface layer of the source-drain regions 54, as shown in FIG. 11A.

Then, after forming an interlayer insulation film 58 over the entire surface of the semiconductor substrate 51, contact holes are formed in the interlayer insulation film 58 over the source-drain regions 54, and metal (aluminum, for example) interconnections 60 are formed on the source-drain regions 54 through a barrier metal film 59, as shown in FIG. 11B.

Further description on the technologies mentioned above is disclosed in Japanese Patent Application Publication No. 2000-12487, for example.

A process step to implant impurity ions into a polysilicon film to form a polysilicon resistor has been shared with a process step to implant impurity ions into source-drain regions in manufacturing the semiconductor device using the silicide process.

A dose of the impurity ions implanted in this process step has been about 2-5×10¹⁵/cm². That is, sharing the process step with the impurity ion implantation to form the source-drain regions makes the dose of the impurity ions implanted into the polysilicon resistor layer high, because the forming of the source-drain regions requires a high dose of impurity ions to be implanted. It raised a problem that a sheet resistance in the polysilicon resistor layer formed by the conventional method was 500 Ω/□ at most, which made a polysilicon resistor having a resistance as high as 10MΩ and used as a feed back resistor of a quartz oscillator too big in size, for example.

### SUMMARY OF THE INVENTION

The invention provides a method of manufacturing a semiconductor device. The method includes providing a semiconductor substrate, forming an insulation film on the semiconductor substrate, forming a polysilicon film on the insulation film, implanting a first impurity into the polysilicon film, forming a gate electrode and a resistor layer by patterning the implanted polysilicon film, implanting a second impurity into the semiconductor substrate to form a source region and a drain region adjacent the gate electrode while the resistor layer is covered with a mask, and forming a silicide film on the gate electrode, the source region, the drain region and part of the resistor layer.

The invention also provides another method of manufacturing a semiconductor device. The method includes providing a semiconductor substrate, forming an insulation film on the semiconductor substrate, forming a polysilicon film on the insulation film, implanting a first impurity into the polysilicon film, forming a gate electrode and a resistor layer by patterning the implanted polysilicon film, implanting a second impurity into the semiconductor substrate to form a low impurity concentration source region and a low impurity concentration drain region adjacent the gate electrode while the resistor layer is covered with a mask, forming a sidewall insulation film on a sidewall of the gate electrode, implanting a third impurity into the semiconductor substrate to form a high impurity concentration source region and a high impurity concentration drain region adjacent the sidewall insulation film while the resistor layer is covered with a mask, and forming a silicide film on the gate electrode, the source region, the drain region and part of the resistor layer.

### BRIEF DESCRIPTION OF THE DRAWINGS

FIG. 1 is a cross-sectional view showing a manufacturing method of a semiconductor device according an embodiment of this invention.

FIG. 2 is a cross-sectional view showing the manufacturing method of the semiconductor device according the embodiment of this invention.

FIG. 3 is a cross-sectional view showing the manufacturing method of the semiconductor device according the embodiment of this invention.

FIG. 4 is a cross-sectional view showing the manufacturing method of the semiconductor device according the embodiment of this invention.

FIG. 5 is a cross-sectional view showing the manufacturing method of the semiconductor device according the embodiment of this invention.

FIG. 6 is a cross-sectional view showing the manufacturing method of the semiconductor device according the embodiment of this invention.

FIG. 7 is a cross-sectional view showing the manufacturing method of the semiconductor device according the embodiment of this invention.

FIG. 8 is a cross-sectional view showing the manufacturing method of the semiconductor device according the embodiment of this invention.

FIG. 9 is a plan view showing the manufacturing method of the semiconductor device according the embodiment of this invention.

FIGS. 10A and 10B are cross-sectional views showing a manufacturing method of a semiconductor device according to a prior art.

FIGS. 11A and 11B are cross-sectional views showing the manufacturing method of the semiconductor device according to the prior art.

### DETAILED DESCRIPTION OF THE INVENTION

A manufacturing method of a semiconductor device according to an embodiment of this invention will be explained hereinafter referring to the drawings.

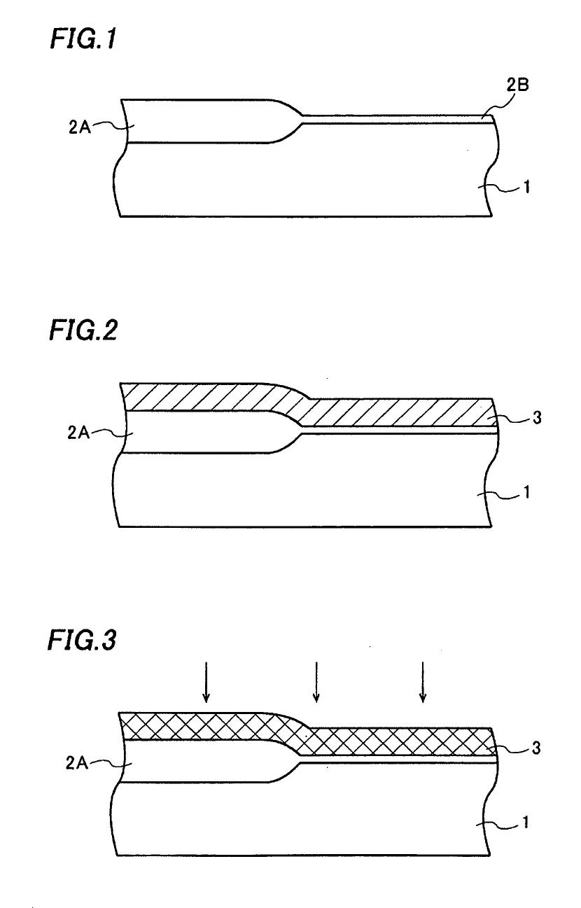

First, as shown in FIG. 1, a device isolation film 2A is formed on a semiconductor substrate 1 of one conductivity type, that is P-type for example, and an insulation film 2B is formed on a region of the semiconductor substrate 1 where the device isolation film 2A is not formed.

Then, an undoped polysilicon film 3 is formed over an entire surface of the semiconductor substrate 1, as shown in FIG. 2, and impurity ions are implanted into an entire surface of the polysilicon film 3, as shown in FIG. 3. Here, a dose of the impurity ions implanted is about 5×10¹⁴/cm², for example, and the impurity ions are selected from among ions of boron, boron difluoride, phosphorus and arsenic.

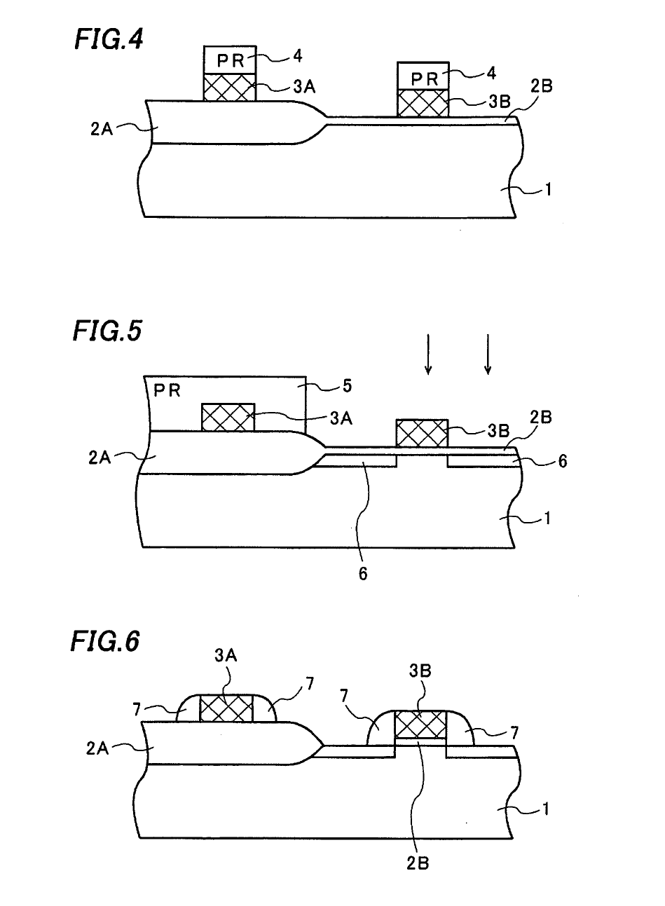

Next, a resistor layer 3A is formed on the device isolation film 2A while a gate electrode 3B is formed on the insulation film 2B (gate insulation film) by patterning the polysilicon film 3 with a mask of a photoresist film 4 formed on the polysilicon film 3, as shown in FIG. 4.

After that, low impurity concentration source-drain regions 6 are formed by implanting impurity ions of opposite conductivity type, that is N-type for example, into a surface layer of the semiconductor substrate 1 adjacent the gate electrode 3B using a mask of a photoresist film 5 formed over the device isolation film 2 including the resistor layer 3A, as shown in FIG. 5. In this process step, phosphorus ions of a dose of 3×10¹³/cm² are implanted at 30 KeV, for example.

Next, after removing the photoresist film 5, an insulation film is formed over the entire surface of the semiconductor substrate 1 and the insulation film is anisotropically etched to form a sidewall insulation film 7 on each sidewall of the resistor layer 3A and the gate electrode 3B, as shown in FIG. 6. At that time, the insulation film 2B on regions where high impurity concentration source-drain regions 9 are to be formed is removed.

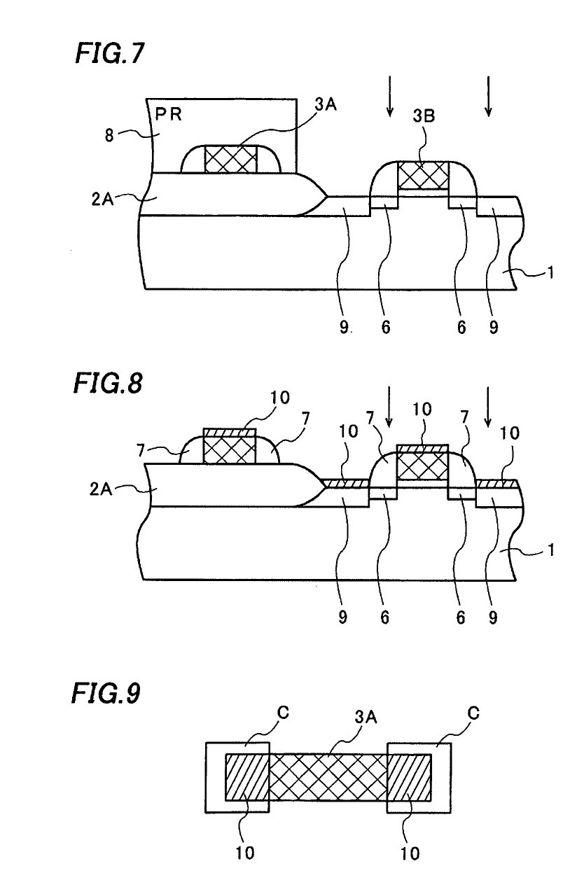

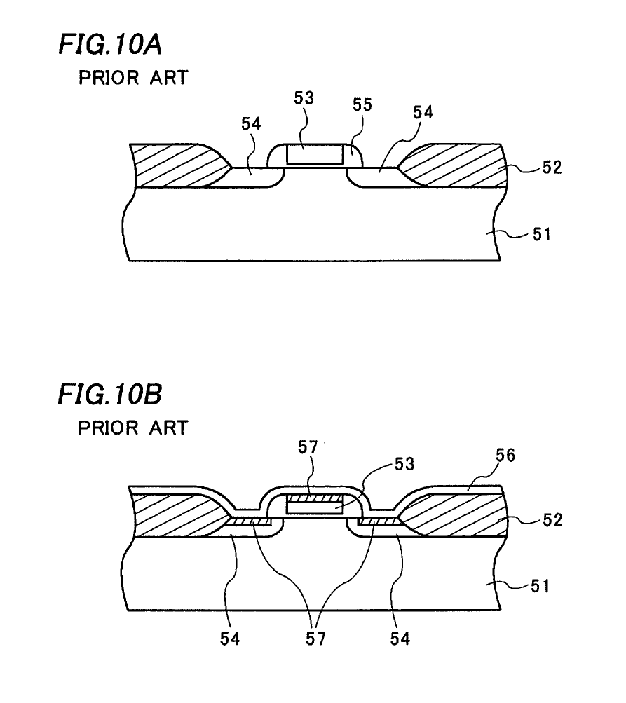

After that, the high impurity concentration source-drain regions 9 are formed by implanting impurity ions of the opposite conductivity type, that is N-type for example, into the surface layer of the semiconductor substrate 1 adjacent the sidewall insulation film 7 using a mask of a photoresist film 8 formed over the device isolation film 2 including the resistor layer 3A, as shown in FIG. 7. In this process step, arsenic ions of a dose of 2-5×10⁵/cm² are implanted at 40 KeV, for example.

Next, after forming an insulation film over the entire surface of the semiconductor substrate 1, only regions where silicide is to be formed are exposed using a mask of photoresist film, although a drawing of the device structure at this process step is omitted. Here, the regions where the silicide is to be formed mean a surface layer of the gate electrode 3B, a surface layer of the high impurity concentration source-drain regions 9 shown in FIG. 8 and contact regions C on a surface layer of the resistor layer 3A shown in FIG. 9. Then a titanium silicide (TiSi₂) film 10 is formed by depositing a titanium (Ti) film over the entire surface of the semiconductor substrate 1 followed by a thermal treatment, such as RTA (rapid thermal annealing), to transform the contact regions C on a surface layer of the resistor layer 3A, the surface layer of the gate electrode 3B and the surface layer of the high impurity concentration source-drain regions 9 into silicide selectively and in a self-aligned manner, as shown in FIG. 8. The RTA treatment is performed in two steps to prevent excessive silicidation. For example, the first step of the RTA treatment is done at about 650-700° C. for 30 seconds, and the second step of the RTA treatment is done at about 750-850° C. for 30 seconds after removing the remaining titanium film that has not been transformed into silicide in the first step.

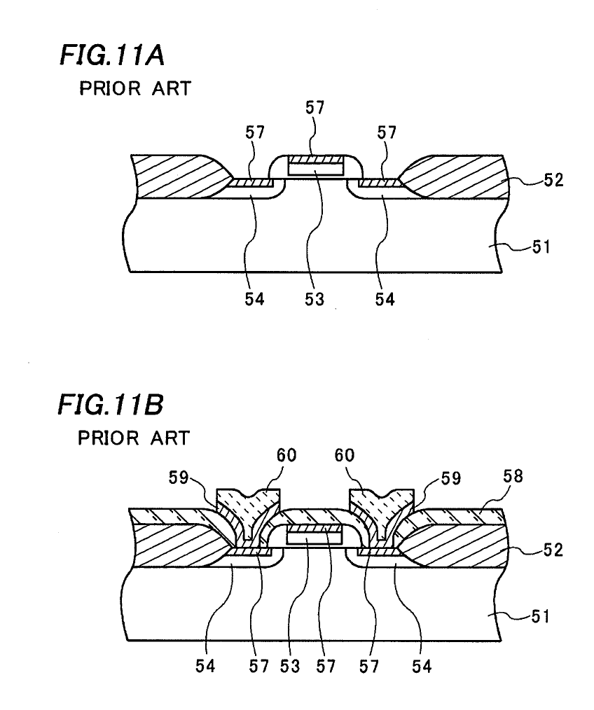

Then, after forming an interlayer insulation film over the entire surface of the semiconductor substrate 1, contact holes are formed in the interlayer insulation film over the resistor layer 3A, the gate electrode 3B and the high impurity concentration source-drain regions 9, and metal (mainly consisting of aluminum or copper, for example) interconnections are formed to make contact with them through a barrier metal film, as in the prior art shown in FIG. 11B.

As a result, the sheet resistance of the polysilicon resistor that has been about 500Ω/□ in the prior art can be increased to as high as about 10KΩ/□ with the semiconductor device according to the embodiment of this invention. Therefore, a resistor of about 10MΩ used as a feed back resistor of a quartz oscillator can be formed in a small area. A manufacturability is improved with the manufacturing method according to the embodiment of this invention, because the polysilicon resistor of higher resistance than available with the prior art can be formed by adding only one impurity ion implantation into the polysilicon film without using a mask, besides impurity ion implantation to form the source-drain regions.

Although the embodiment is described only for the N-channel type MOS transistor, the manufacturing process described in the embodiment applies to a P-channel type MOS transistor similarly. Also, a metal silicide film other than the titanium silicide film, a cobalt silicide film for example, may be used as the silicide film.

According to the embodiment of this invention, the polysilicon resistor having a resistance higher than the resistance available with the prior art can be formed by adding only one impurity ion implantation into the polysilicon film without using a mask, besides impurity ion implantation to form the source-drain regions.

What is claimed is:

1. A method of manufacturing a semiconductor device, comprising:
providing a semiconductor substrate;
forming an insulation film on the semiconductor substrate;
forming a polysilicon film on the insulation film;
implanting a first impurity into the polysilicon film;
forming a gate electrode and a resistor layer by patterning the implanted polysilicon film;
implanting a second impurity into the semiconductor substrate to form a source region and a drain region adjacent the gate electrode while the resistor layer is covered with a mask; and
forming a silicide film on the gate electrode, the source region, the drain region and part of the resistor layer.

2. The method of claim 1, wherein the insulation film comprises a first insulation film and a second insulation film that is thinner than the first insulation film, and the first and second insulation films are juxtaposed and in contact with each other.

3. The method of claim 1, wherein the drain region comprises a low impurity concentration region and a high impurity concentration region.

4. The method of claim 1, wherein the silicide film comprises a titanium silicide film or a cobalt silicide film.

5. The method of claim 3, wherein the silicide film comprises a titanium silicide film or a cobalt silicide film.

6. A method of manufacturing a semiconductor device, comprising:
providing a semiconductor substrate;
forming an insulation film on the semiconductor substrate;
forming a polysilicon film on the insulation film;
implanting a first impurity into the polysilicon film;
forming a gate electrode and a resistor layer by patterning the implanted polysilicon film;
implanting a second impurity into the semiconductor substrate to form a low impurity concentration source region and a low impurity concentration drain region adjacent the gate electrode while the resistor layer is covered with a mask;
forming a sidewall insulation film on a sidewall of the gate electrode;
implanting a third impurity into the semiconductor substrate to form a high impurity concentration source region and a high impurity concentration drain region adjacent the sidewall insulation film while the resistor layer is covered with a mask; and
forming a silicide film on the gate electrode, the source region, the drain region and part of the resistor layer.

7. The method of claim 6, wherein the insulation film comprises a first insulation film and a second insulation film that is thinner than the first insulation film, and the first and second insulation films are juxtaposed and in contact with each other.

8. The method of claim 6, wherein the silicide film comprises a titanium silicide film or a cobalt silicide film.
